(19) United States
(12) Patent Application Publication
(10) Pub. No.: US 2010/0208920 A1
(43) Pub. Date: Aug. 19, 2010

(54) ELECTRONIC DEVICE MANUFACTURED BY MOLDING, METHOD AND MOLD FOR MANUFACTURING THE SAME, AND ELECTRONIC APPLICATION USING THE SAME

(75) Inventors: Duk Woo LEE, Suwon (KR); Jae Suk SUNG, Yongin (KR); Dae Kyu LEE, Suwon (KR); Tae Seok YANG, Seoul (KR); Young Ho JEON, Seoul (KR)

Correspondence Address: LOWE HAUPTMAN HAM & BERNER, LLP, 1700 DIAGONAL ROAD, SUITE 300, ALEXANDRIA, VA, 22314, US

(73) Assignee: Samsung Electro-Mechanics Co., Ltd., Suwon (KR)

(21) Appl. No.: 12/629,672

(22) Filed: Dec. 2, 2009

(30) Foreign Application Priority Data
Feb. 16, 2009 (KR) 10-2009-0012410

(51) Int. Cl. H04R 3/00; H05K 5/00; B29C 45/14

(52) U.S. Cl. 381/122; 361/752; 264/263; 425/129.1

(57) ABSTRACT

An electronic device manufactured by molding according to an aspect of the invention may include a board having a circuit component mounted thereon; a cable transmitting a signal from an external source to the board; a clamp securing the cable to the board; and a casing molding unit integrally molded with the board and the clamp from a resin material to define the outer appearance.

### CROSS-REFERENCE TO RELATED APPLICATIONS

This application claims the priority of Korean Patent Application No. 10-2009-0012410 filed on Feb. 16, 2009, in the Korean Intellectual Property Office, the disclosure of which is incorporated herein by reference.

### BACKGROUND OF THE INVENTION

1. Field of the Invention

The present invention relates to an electronic device manufactured by molding, a method and mold for manufacturing the same, and an electronic application using the same, and more particularly, to an electronic device molded integrally with a board, having a driving circuit component mounted thereon, from a resin material, the driving circuit component that supplies a signal upon being pressed and then returns to its original state.

2. Description of the Related Art

In general, electronic devices in which cables or circuit components mounted onto boards are formed are manufactured in such a way that these circuit components or cables are connected first and upper and lower cases are then coupled to each other.

Electronic applications, including remote controllers used for the remote wakeup of vehicles, TVs or wireless communication devices, or controllers of sound devices, such as headphones and earsets, are manufactured using electronic devices having the above-described configuration.

These electronic devices include a smaller number of components than the number of components of electronic applications, such as cellular phones, have a relatively simple structure and are mass produced at low cost.

Recently, these electronic components have also required the inclusion of driving components, such as switches. The internal circuit elements of these switches transmit signals upon being pressed, and then return to their normal state.

To this end, according to a method that has currently been used, a driving component, which serves as the driving unit of an electronic device, is mounted onto aboard, and the driving component is coupled with upper and lower cases having holes formed therein through which the driving unit is exposed.

However, this method includes a process of preparing separate upper and lower cases by molding, and a process of coupling the upper and lower cases with each other is further performed. This complicates the production process.

In addition, products are difficult to waterproof because gaps are formed between the driving unit and the case.

When an electronic device having cables connected thereto is manufactured, the cables are bound together within the cases of the electronic device.

However, such a manufacturing method increases the size of the electronic device, reduces utilization of internal space, and prevents product miniaturization.

Further, since cables are bound, the electronic device is vulnerable to external forces such as cable bending or push-pull movements.

### SUMMARY OF THE INVENTION

An aspect of the present invention provides an electronic device molded integrally with a circuit component, mounted onto a board, supplying a signal upon being pressed and then returning to its original state, and other general circuit components, a method and mold for manufacturing the same, and an electronic device using the same According to an aspect of the present invention, there is provided an electronic device manufactured by molding, the electronic device including: a board having a circuit component mounted thereon; a cable transmitting a signal from an external source to the board; a clamp securing the cable to the board; and a casing molding unit integrally molded with the board and the clamp from a resin material to define the outer appearance.

The clamp may include a clamp rack, and the clamp rack may be inserted and fixed into a rack insertion hole in the board.

A driving unit supplying a signal upon being pressed and then returning to its original state may further be mounted onto the board, and the driving unit may be molded by a driving unit mold casing unit molded integrally with the casing molding unit.

The driving mold casing unit and the casing molding unit may be differentiated from each other by a difference in mold thickness.

The driving unit may include: a button received in a button receiving portion within the protective cap; and a switch controlling an electrical signal by pushing the button.

The protective cap may include the button receiving portion provided on the partition and receiving the button.

A positioning hole for determining the positions of the switch and the button may be provided in the button receiving portion, and a protrusion extending from the button may be inserted into the positioning hole.

A microphone may be further mounted on the board, and a sound transmission hole may be provided in the casing molding unit at a position corresponding to the microphone.

The electronic device may further include a protective cap covering the driving unit or the microphone on the board and preventing the direct molding of the driving unit or the microphone.

A sound passing hole corresponding to the sound transmission hole may be provided in the protective cap covering the microphone, and a mesh may be bonded to the sound passing hole to provide waterproofing.

A portion of the clamp may extend outside the board, and a clamp molding unit corresponding to the portion of the clamp extending outside the board may be molded integrally with the casing molding unit.

A support pin hole may be provided in the board so that a support pin of a mold is inserted into the support pin hole to fix the board in the mold.

According to another aspect of the present invention, there is provided a method of manufacturing an electronic device, the method including: securing a cable to a board so that the board and the cable are connected to each other; fixing the board, having the cable secured thereto, within a cavity between upper and lower molds by inserting a support pin, extending from the upper mold, the lower mold or the upper and lower molds, into the board; and injecting a resin material through a resin material injection portion formed at one side of the upper mold, the lower mold or the upper and lower molds so that spaces between the upper and lower molds and the board form a driving unit mold casing unit and a casing molding unit.

The clamp molding unit corresponding to the clamp extending outside the board may be molded integrally with the casing molding unit when a portion of the clamp extends outside the board.

When a microphone is mounted onto the board, molding may be performed while a sound transmission hole forming pin of the upper or lower mold is in contact with the microphone, so that a sound transmission hole is formed in the casing molding unit at a position corresponding to the microphone.

A support pin hole in the board may include at least one pin hole formed in the edge of the board.

According to another aspect of the present invention, there is provided a mold for manufacturing an electronic device, the mold including: upper and lower molds in which a board connected to a cable through a clamp is arranged; a support pin extending from the upper mold, the lower mold or the upper and lower molds and engaged with a support pin hole provided in the board to thereby secure the board within a cavity between the upper and the lower molds; and a resin material injection portion provided at the upper mold, the lower mold, or the upper or lower molds, the resin material injection portion through which a resin material is injected into the cavity so that the cavity between the upper and lower molds forms a casing molding unit.

The support pin may be provided in the upper or lower mold at a position corresponding to the support pin hole provided in the edge of the board.

When a microphone is mounted onto the board, molding may be performed while a sound transmission hole forming pin of the upper or lower mold is in contact with the microphone, so that a sound transmission hole is formed in the casing mold unit at a position corresponding to the microphone.

A portion of the clamp may extend outside the board, and the mold may further include a clamp molding unit forming portion forming a clamp molding unit corresponding to the portion of the clamp extending outside the board.

The mold may further include a support line forming portion forming a support line along an outer circumferential edge of the casing molding unit to maintain the outer appearance.

According to another aspect of the present invention, there is provided a sound transmission device including: a casing molding unit integrally molded with a board, to which a cable is connected through a clamp, and a driving unit including a switch and a button separated from each other by a partition of a protective cap, the driving unit supplying a signal upon the button being pushed and then returning to its original state; a jack engaging portion extending from one side of the casing molding unit and being supplied with a sound signal; and a speaker connected to the other side of the casing molding unit and producing sound being controlled by pressing the driving unit.

The casing molding unit may be distinguished from the driving mold casing unit covering the driving unit by a difference in mold thickness.

A support line may be provided along an outer circumferential edge of the casing molding unit to maintain the outer appearance.

A microphone may be further mounted within the casing molding unit, and a sound transmission hole may be provided in the casing molding unit at a position corresponding to the microphone.

A sound passing hole corresponding to the sound transmission hole may be provided in a protective cap covering the microphone, and a mesh may be bonded to the sound passing hole to provide waterproofing.

The protective cap may include a button receiving portion provided on the partition and receiving the button.

A positioning hole may be provided in the button receiving portion to determine the positions of the switch and the button, and a protrusion extending from the button may be inserted into the positioning hole.

A portion of the clamp may extend outside the board, and a clamp molding unit corresponding to the portion of the clamp extending outside the board may be molded integrally with the casing molding unit.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional perspective view partially illustrating an electronic device that is manufactured by molding according to an exemplary embodiment of the present invention;

FIG. 2 is an exploded perspective view schematically illustrating an electronic device of FIG. 1 before being manufactured by molding;

FIG. 3 is a side cross-sectional view illustrating the assembled electronic device, shown in FIG. 2;

FIG. 4 is a schematic perspective view illustrating a clamp of a cable that is connected to an electronic device according to an exemplary embodiment of the present invention;

FIG. 5 is a schematic perspective view illustrating how the clamp, shown in FIG. 4, is connected to a board, as viewed from the bottom;

FIG. 6 is a schematic view illustrating the way in which an electronic device is placed in a mold before molding according to an exemplary embodiment of the present invention;

FIG. 7 is a schematic view illustrating resin materials being injected into the mold of FIG. 6;

FIG. 8 is a first electronic application according to an exemplary embodiment of the present invention; and

FIG. 9 is a second electronic application using an electronic device according to an exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as limited to the embodiments set forth herein. Those skilled in the art will understand that various additions, alterations and deletions may be made without departing from the intended spirit and scope of the invention and easily propose other exemplary embodiments falling within the spirit of the invention or another invention. Accordingly, it is intended that all such additions, alterations and deletions be included within the scope of the following claims and/or the equivalents thereof.

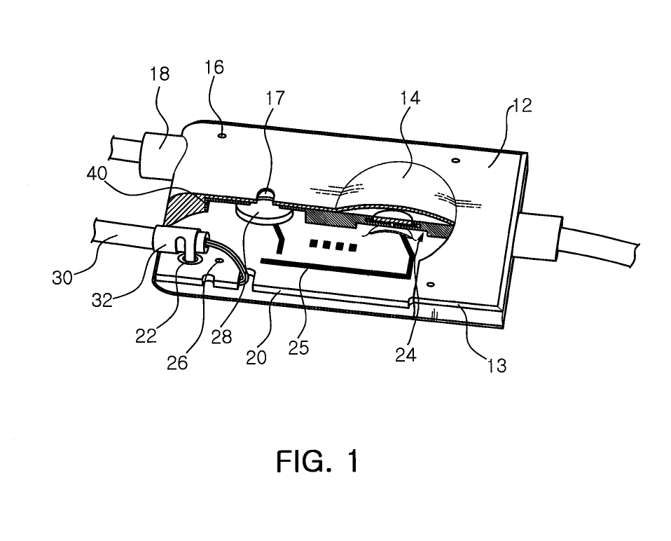

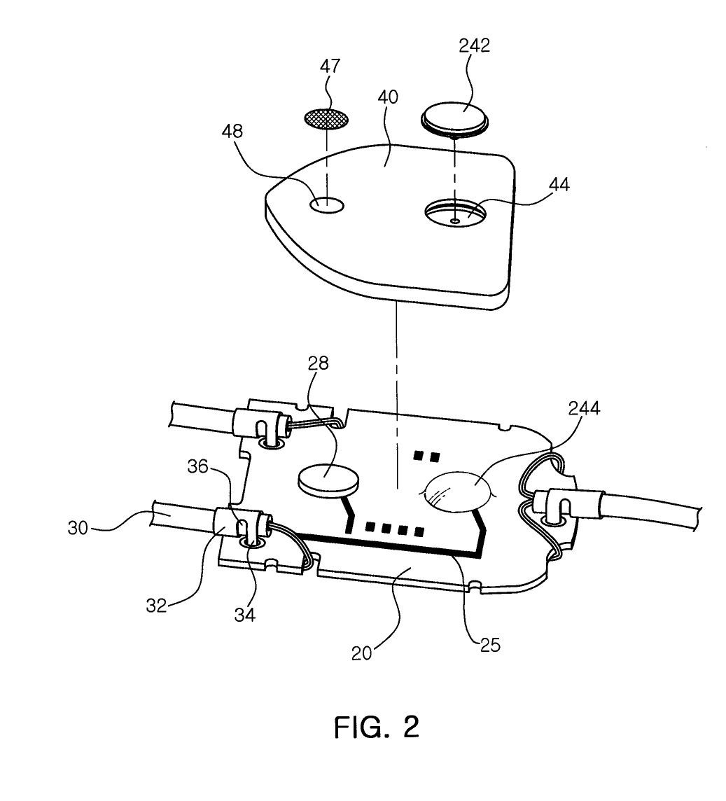

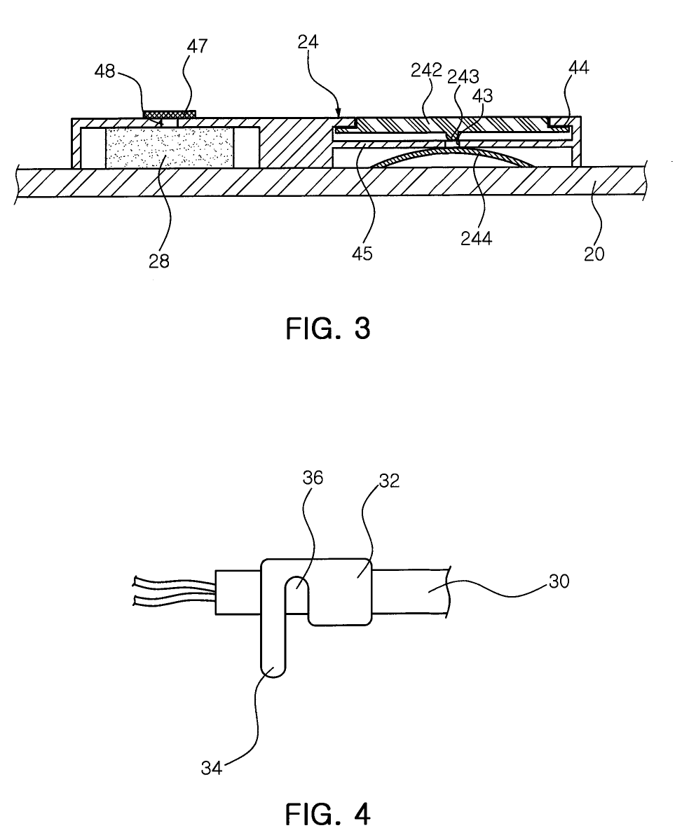

FIG. 1 is a cross-sectional perspective view partially illustrating an electronic device that is manufactured by molding according to an exemplary embodiment of the invention. FIG. 2 is an exploded perspective view schematically illustrating an electronic device of FIG. 1 before being manufactured by molding. FIG. 3 is a side cross-sectional view illustrating the assembled electronic device, shown in FIG. 2.

Referring to FIGS. 1 through 3, an electronic device 10 that is manufactured by molding according to this embodiment includes a driving unit 24, a board 20, a driving unit mold casing unit 14, and a casing molding unit 12.

The driving unit 24 is one of the circuit components that are formed on the board 20. Specifically, the driving unit 24 is a circuit component that supplies an electric signal upon being pressed, and then returns to its original state. The driving unit 24 is mounted onto the board 20 on which circuit patterns 25 are formed.

The driving unit 24 may include a button 242 and a switch 244. The button 242 is received in a button receiving portion 44 within a protective cap 40, and is pressed and returns to its original state. The switch 244 supplies an electrical signal to the board 20.

As for the board 20, surface-mount devices may be used for the miniaturization of the electronic device 10.

Meanwhile, when insert molding is performed using resin materials, used for general molding, such as PC or PC/ABS resins, with respect to the board 20, the surface-mount devices may be separated from the board 20. Therefore, the board 20 is covered with the protective cap 40, which is then subjected to molding.

That is, the protective cap 40 covers the driving unit 24 and prevents the direct molding of the driving unit 24. Further, the button receiving portion 44 is formed in the protective cap 40. The button receiving portion 44 is provided on a partition 45 that is interposed between the button 242 and the switch 244. The button receiving portion 44 creates space allowing the button 242 to be pressed and return to its original state.

A positioning hole 43 is formed in the button receiving portion 44 to determine the positions of the switch 244 and the button 242. A protrusion 243 extending from the button 242 may be inserted into the positioning hole 43.

That is, as the protrusion 243 is inserted into the positioning hole 43, the positions of the switch 244 and the button 242 are determined. The protrusion 243 and the positioning hole 43 may correspond to the centers of the button 242 and the switch 244.

Here, the protective cap 40 may be formed of rubber, and the button 242 may be formed of plastic resins. After the protective cap 40 is subjected to molding, when the driving unit mold casing unit 14 is pressed to thereby push the button 242, the button 242, which is a solid object, presses the partition 45, formed of rubber, thereby facilitating power transmission.

When an elastomer having a lower melting point and high fluidity is used as the resin material, the molding process can be performed stably without damaging the surface-mount devices even when the protective cap 40 is not used.

A component, such as a microphone 28, may be mounted onto the board 20. A sound transmission hole 17 may be formed in the casing molding unit 12 of the electronic device 10 so that sound can be easily transmitted to the microphone 28.

A sound passing hole 48 corresponding to the sound transmission hole 17 is formed in the protective cap 40 that covers the microphone 28. A mesh 47 may be bonded to the sound passing hole 48 in order to provide waterproofing.

The mesh 47 can prevent dust, coming through the sound transmission hole 17, from being directly injected into the microphone 28.

The board 20 is placed on a mold, which is then subjected to the molding process. The molded part forms the external appearance of the electronic device 10.

The external appearance of the electronic device 10 includes the driving unit mold casing unit 14 and the casing molding unit 12. The driving unit mold casing unit 14 is molded with the driving unit 24 from a resin material such that the driving unit 24 can be driven. The casing molding unit 12 is obtained by molding to completely cover the board 20 together with the driving unit mold casing unit 14.

When a user presses the driving unit 24 in order to operate the electronic device 10, the driving unit mold casing unit 14 and the casing molding unit 12 may be distinguished from each other by a division line 15 so that the driving unit 24 can be easily identified.

The difference in height of the mold forms the division line 15. The difference in mold thickness of the driving unit mold casing unit 14 and the casing molding unit 12 determines the difference in height between the molds.

In order to maintain the external shape of the casing molding unit 12, a support line 13 is formed along the outer circumferential edge of the casing molding unit 12. The support line 13 may include a plurality of support lines that are formed along the edges of the casing molding unit 12 in order to maintain the external shape of the casing molding unit 12.

The molding process is performed on the board 20 after the board 20 is placed within the mold. Since the molding process needs to be performed on the top and bottom of the board 20 simultaneously, the board 20 also needs to be placed within a cavity of the mold.

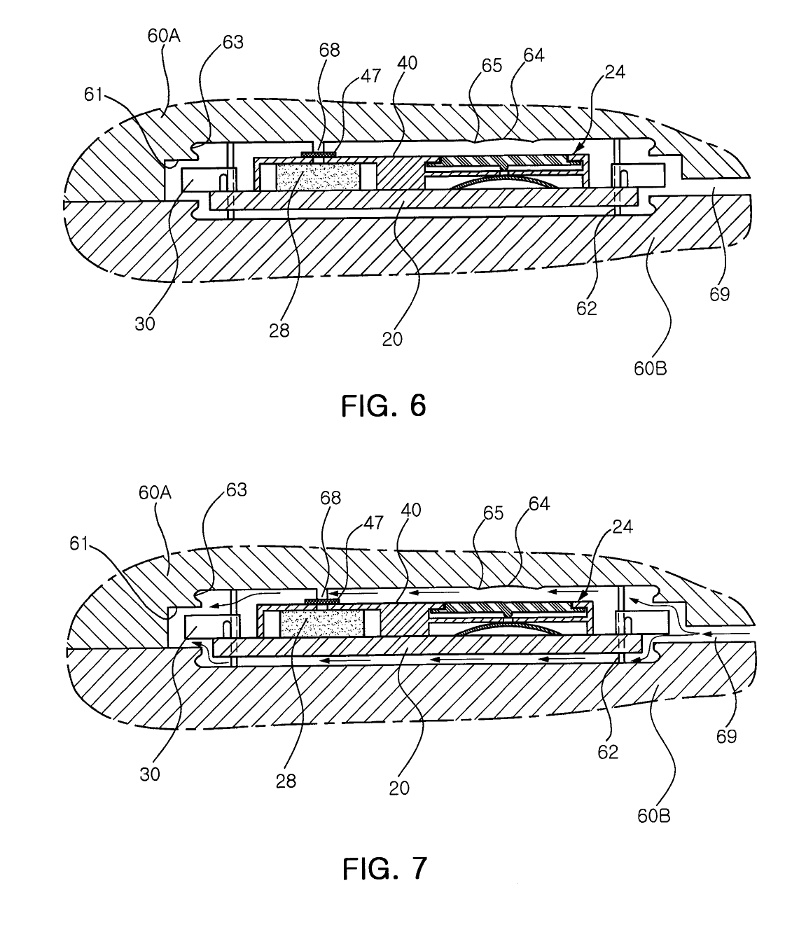

To this end, a support pin hole 26 may be formed in the board 20 so that a support pin 62 of a mold 60, shown in FIG. 6, is inserted into the support pin hole 26 and the board 20 is secured inside the mold 60.

Since the molding process is performed while the support pin 62 within the mold is inserted into the support pin hole 26 of the board 20, a support pin hole 16 may also be formed in the casing molding unit 12 after molding.

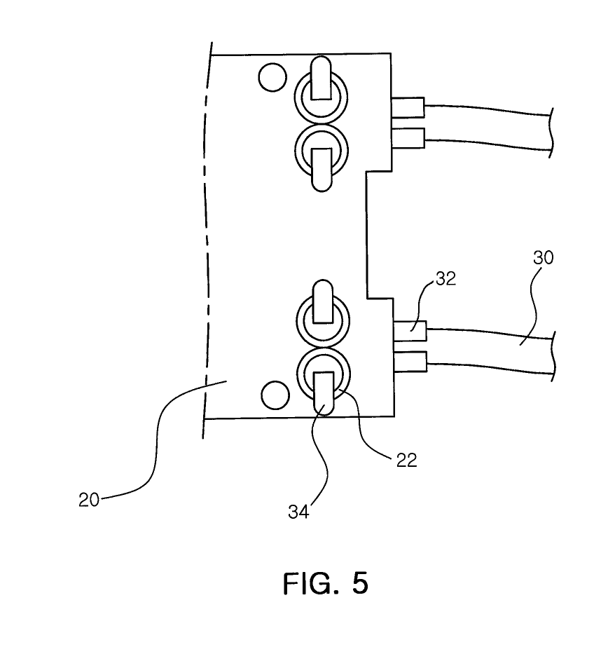

FIG. 4 is a schematic perspective view illustrating a clamp of a cable that is connected to an electronic device according to an exemplary embodiment of the invention. FIG. 5 is a schematic perspective view illustrating how the clamp, shown in FIG. 4, is connected to a board, as viewed from the bottom.

An electronic device 10 according to another exemplary embodiment of the invention may include aboard 20, a cable 30, a clamp 32, and a casing molding unit 12.

The electronic device 10 according to this embodiment is different from the electronic device 10 according to the embodiment, described with reference to FIGS. 1 through 3, in that the cable 30 is connected to the board 20 by the use of the clamp 32. Other components of the embodiment, described with reference to FIGS. 1 through 3, can be applied to this embodiment.

The cable 30 for supplying a signal from the outside is connected to the board 20 through the clamp 32. The clamp 32 may allow the cable 30 to be fixed to the board 20.

The clamp 32 is formed of a thin metal that encompasses the cable 30, and includes a clamp rack 34

The clamp rack 34 is inserted and fixed into a rack insertion hole 22 in the board 20.

A portion of the clamp 32 extends outside the board 20. A clamp molding unit 18 (refer to FIG. 1) corresponding to the portion of the clamp 32 extending outside the board 20 is molded integrally with the casing molding unit 12.

Hereinafter, a method and mold for manufacturing the above-described embodiments will be described with reference to FIGS. 6 and 7.

FIG. 6 is a schematic view illustrating the way in which an electronic device is placed in a mold before molding according to an exemplary embodiment. FIG. 7 is a schematic view illustrating resin materials being injected into the mold of FIG. 6.

Referring to FIGS. 6 and 7, a method of manufacturing an electronic device according to an exemplary embodiment of the invention will be described.

In order to manufacture the electronic device 10 according to the embodiment, described with reference to FIGS. 1 through 3, the board 20 is placed in upper and lower molds 60A and 60B in which the driving unit 24, mounted on the board 20, supplying a signal upon being pressed and then returning to its original state, is distinguished from other circuit components.

Here, when the board 20 is placed in the upper and lower molds 60A and 60B, the board 20 may be covered with a protective cap 40 in order to prevent the direct molding of the driving unit on the board 20.

Further, in case the microphone 28 is mounted onto the board 20, the molding process may be performed while a sound transmission hole forming pin 68 of the upper or lower mold 60A or 60B is in contact with the microphone 28 so that a sound transmission hole 17 is formed in the casing molding unit 12 corresponding to the microphone 28. Furthermore, after the sound transmission hole forming pin 68 makes contact with the mesh 47 on the protective cap 40, the molding process may be performed.

Then, the support pin 62, extending from any one of the upper and lower molds 60A and 60B, is inserted into the support pin hole 26 of the board 20, so that the board 20 is fixed to the cavity between the upper and lower molds 60A and 60B.

Here, one or more support pin holes 26 of the board 20 may be formed in the edges of the board 20.

Then, resin materials are injected at low pressure through a resin injection portion 69 that is formed at the sides of the upper and lower molds 60A and 60B. Spacing between the mold 60 and the board 20 forms the driving unit mold casing unit 14 and the casing molding unit 12.

As for a method of manufacturing the electronic device 10 according to the embodiment shown in FIGS. 4 and 5, the above-described manufacturing method can be used, except for a process of connecting the cable 30 to the board 20 through the clamp 32.

That is, the method of manufacturing an electronic device according to this embodiment includes fixing the cable 30 to the board 20 using the clamp 32.

When a portion of the clamp 32 extends outside the board 20, the portion of the clamp 32 is appropriately disposed in the upper and lower molds 60A and 60B so that the clamp molding unit 18 that corresponds to the portion of the clamp 32, extending outside the board 20 is molded integrally with the casing molding unit 12.

Referring to FIGS. 6 and 7, a mold for manufacturing an electronic device according to an exemplary embodiment of the invention will be described.

The mold 60 for manufacturing the electronic device 10 according to the embodiment, described with reference to FIGS. 1 through 3, includes the upper and lower molds 60A and 60B, the support pin 62, and the resin injection portion 69.

The board 20 having the driving unit 24, supplying a signal upon being pressed and then returning to its original state, mounted thereon is disposed within the upper and lower molds 60A and 60B.

The board 20 may be disposed while circuit components are provided on the top thereof. Alternatively, the board 20 may be disposed while circuit components are provided on the bottom thereof. That is, the top and the bottom are interchangeable with each other.

The support pin 62, which extends from any one of the upper and lower molds 60A and 60B and is formed in the board 20, is engaged with the support pin hole 26, thereby fixing the board 20 within the cavity between the upper and lower molds 60A and 60B.

Here, the support pin 62 may be formed on the upper or lower mold 60A or 60B that corresponds to the support pin hole 26 that is formed in the edge of the board 20.

The resin material injection portion 69 may be formed at the upper mold 60A, the lower mold 60B or the upper and lower molds 60A and 60B. Further, the resin materials are injected through the resin material injection portion 69 so that the cavity between the upper and lower molds 60A and 60B forms the driving unit mold casing unit 14 and the casing molding unit 12.

When the microphone 28 is mounted on the board 20, the sound transmission hole forming pin 68 may extend from the upper or lower mold 60A or 60B so that the sound transmission hole 17 is formed in the casing molding unit 12 corresponding to the microphone 28.

Further, the mold 60 may further include a division line forming portion 65 that distinguishes the driving unit mold casing unit 14 from the casing molding unit 12. The division line forming portion 65 may have a similar shape to the driving unit 24. A recess 64 may also be formed inside the division line forming portion 65 so that the driving unit mold casing unit 14 will have a different height.

The mold 60 may include a support line forming portion 63 that forms the support line 13 along the outer circumferential edge of the casing molding unit 12 so as to maintain the external shape.

A mold for manufacturing the electronic device 10 according to the embodiment, shown in FIGS. 4 and 5, has the same components as the above-described mold except that molding is performed on the board 20 to which the cable 30 is connected through the clamp 32 to thereby integrally form the clamp molding unit 18 by molding.

That is, since a portion of the clamp 32 extends outside the board 20, the mold 60 for manufacturing an electronic device according to this embodiment includes a clamp molding unit forming part 61 that extends outside the board 20.

Various kinds of electronic applications are manufactured using the above-described electronic device 10. Hereinafter, electronic applications will be described.

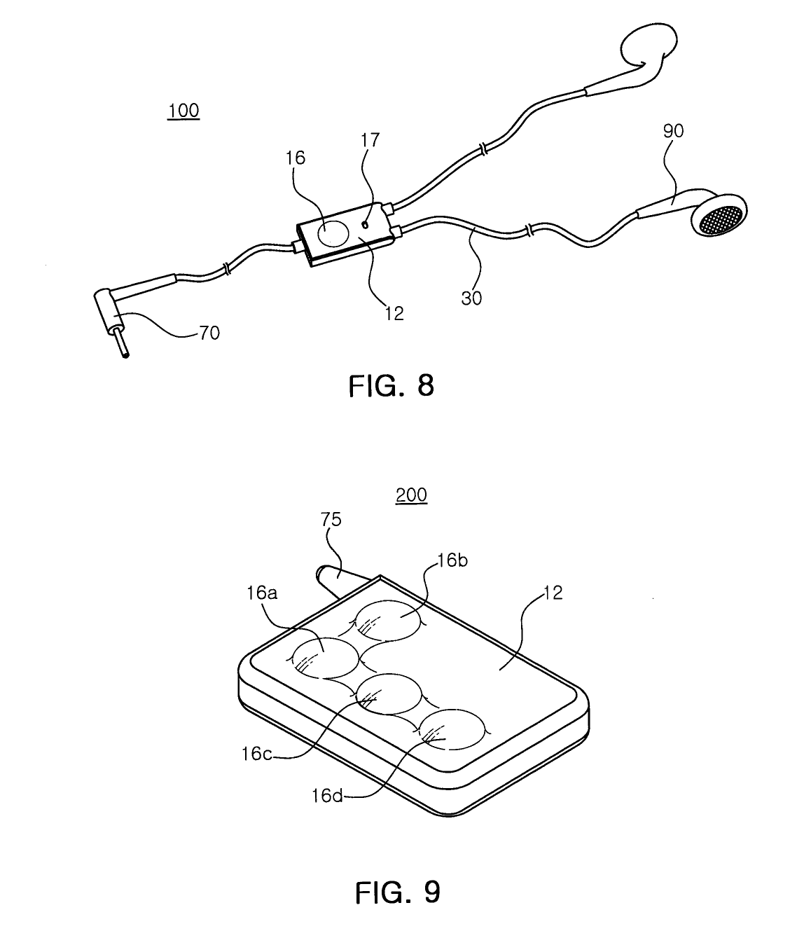

FIG. 8 is a first electronic application according to an exemplary embodiment of the invention.

Referring to FIG. 8, a sound transmitting apparatus 100, such as an earset or a headphone, is manufactured using an electronic device according to an exemplary embodiment of the invention.

The sound transmitting apparatus 100 may include a casing molding unit 12, a jack engaging portion 70, and a speaker 90. The casing molding unit 12 is integrally molded with a driving unit 24 that supplies a signal upon being pressed and returns to its original state. The jack engaging portion 70 extends from one side of the casing molding unit 12, is connected with external sound equipment or a portable terminal, and transmits sound supplied from the external sound equipment or the portable terminal. The speaker 90 is connected to the other side of the casing molding unit 12, and the sound of the speaker 90 is controlled by pressing the driving unit 24.

In this embodiment, a cable is included. The cable 30 is connected to the board 20 through the clamp 32. The clamp molding unit 18 may be formed integrally with the casing molding unit 12.

FIG. 9 is a second electronic application using an electronic device according to an exemplary embodiment of the invention.

Referring to FIG. 9, a wireless remote controller 200, which is used for remote wakeup and remote control, is manufactured using an electronic device according to an exemplary embodiment of the invention.

The wireless remote controller 200 includes a casing molding unit 12 and a signal transmission unit 75. The casing molding unit 12 is molded integrally with driving units 16a, 16b, 16c and 16d, each of which supplies a signal upon being pressed and then returns to its original state, thereby forming the outer casing. The signal transmission unit 75 is provided on one side of the casing molding unit 12 and transmits a signal from the driving unit 24 to an external apparatus for starting a vehicle or an electronic device, such as audio equipment or a TV.

Various kinds of electronic applications including the above-described electronic applications can be manufactured using an electronic device according to an exemplary embodiment of the invention.

As set forth above, an electronic device, a method and mold for manufacturing the same, and an electronic application using the same according to exemplary embodiments of the invention, the same resin materials are molded around a driving unit mold casing unit of a driving unit supplying a signal upon being pressed and then returning to its original state, and a mold casing unit forming the outer appearance, thereby simplifying a manufacturing process in comparison with the existing method of separately manufacturing an external case and a driving unit, and coupling the separate components with each other.

Further, manufacturing costs are significantly reduced since the manufacturing process is simplified.

While the existing method of separately manufacturing an external case and a driving unit and coupling the separate components with each other may not provide waterproofing, products can be waterproofed according to the exemplary embodiments of the invention.

An electronic component can have diversified outer appearances by making changes in the mold design and have an ultra thin profile.

Furthermore, when a microphone is embedded in an electronic application, molding materials are completely molded around other components around the microphone to thereby reduce noise in sound.

A cable is connected to a board using a fixing clamp, which is then subjected to a molding process. Therefore, the resistance of a cable against bending or push-pull movements can be increased.

While the present invention has been shown and described in connection with the exemplary embodiments, it will be apparent to those skilled in the art that modifications and variations can be made without departing from the spirit and scope of the invention as defined by the appended claims.

What is claimed is:

1. An electronic device manufactured by molding, the electronic device comprising:
a board having a circuit component mounted thereon;
a cable transmitting a signal from an external source to the board;
a clamp securing the cable to the board; and
a casing molding unit integrally molded with the board and the clamp from a resin material to define the outer appearance.

2. The electronic device of claim 1, wherein the clamp comprises a clamp rack, and
the clamp rack is inserted and fixed into a rack insertion hole in the board.

3. The electronic device of claim 1, wherein a driving unit supplying a signal upon being pressed and then returning to its original state is further mounted onto the board, and
the driving unit is molded by a driving unit mold casing unit molded integrally with the casing molding unit.

4. The electronic device of claim 3, wherein the driving mold casing unit and the casing molding unit are differentiated from each other by a difference in mold thickness.

5. The electronic device of claim 3, wherein the driving unit comprises:
a button received in a button receiving portion within the protective cap; and
a switch controlling an electrical signal by pushing the button.

6. The electronic device of claim 5, wherein the protective cap comprises the button receiving portion provided on the partition and receiving the button.

7. The electronic device of claim 5, wherein a positioning hole for determining the positions of the switch and the button is provided in the button receiving portion, and
a protrusion extending from the button is inserted into the positioning hole.

8. The electronic device of claim 3, wherein a microphone is further mounted on the board, and
a sound transmission hole is provided in the casing molding unit at a position corresponding to the microphone.

9. The electronic device of claim 8, further comprising a protective cap covering the driving unit or the microphone on the board and preventing the direct molding of the driving unit or the microphone.

10. The electronic device of claim 9, wherein a sound passing hole corresponding to the sound transmission hole is provided in the protective cap covering the microphone, and
a mesh is bonded to the sound passing hole to provide waterproofing.

11. The electronic device of claim 1, wherein a portion of the clamp extends outside the board, and
a clamp molding unit corresponding to the portion of the clamp extending outside the board is molded integrally with the casing molding unit.

12. The electronic device of claim 1, wherein a support pin hole is provided in the board so that a support pin of a mold is inserted into the support pin hole to fix the board in the mold.

13. A method of manufacturing an electronic device, the method comprising:
securing a cable to a board so that the board and the cable are connected to each other;
fixing the board, having the cable secured thereto, within a cavity between upper and lower molds by inserting a support pin, extending from the upper mold, the lower mold or the upper and lower molds, into the board; and
injecting a resin material through a resin material injection portion formed at one side of the upper mold, the lower mold or the upper and lower molds so that spaces between the upper and lower molds and the board form a driving unit mold casing unit and a casing molding unit.

14. The method of claim 13, wherein the clamp molding unit corresponding to the clamp extending outside the board is molded integrally with the casing molding unit when a portion of the clamp extends outside the board.

15. The method of claim 13, wherein when a microphone is mounted onto the board, molding is performed while a sound transmission hole forming pin of the upper or lower mold is in contact with the microphone, so that a sound transmission hole is formed in the casing molding unit at a position corresponding to the microphone.

16. The method of claim 13, wherein a support pin hole in the board comprises at least one pinhole formed in the edge of the board.

17. A mold for manufacturing an electronic device, the mold comprising:
upper and lower molds in which a board connected to a cable through a clamp is arranged;
a support pin extending from the upper mold, the lower mold or the upper and lower molds and engaged with a support pin hole provided in the board to thereby secure the board within a cavity between the upper and the lower molds; and
a resin material injection portion provided at the upper mold, the lower mold, or the upper or lower molds, the resin material injection portion through which a resin material is injected into the cavity so that the cavity between the upper and lower molds forms a casing molding unit.

18. The mold of claim 17, wherein the support pin is provided in the upper or lower mold at a position corresponding to the support pin hole provided in the edge of the board.

19. The mold of claim 17, when a microphone is mounted onto the board, molding is performed while a sound transmission hole forming pin of the upper or lower mold is in contact with the microphone, so that a sound transmission hole is formed in the casing mold unit at a position corresponding to the microphone.

20. The mold of claim 17, wherein a portion of the clamp extends outside the board, and
the mold further comprises a clamp molding unit forming portion forming a clamp molding unit corresponding to the portion of the clamp extending outside the board.

21. The mold of claim 17, further comprising a support line forming portion forming a support line along an outer circumferential edge of the casing molding unit to maintain the outer appearance.

22. A sound transmission device comprising:
a casing molding unit integrally molded with a board, to which a cable is connected through a clamp, and a driving unit including a switch and a button separated from each other by a partition of a protective cap, the driving unit supplying a signal upon the button being pushed and then returning to its original state;
a jack engaging portion extending from one side of the casing molding unit and being supplied with a sound signal; and
a speaker connected to the other side of the casing molding unit and producing sound being controlled by pressing the driving unit.

23. The sound transmission device of claim 22, wherein the casing molding unit is distinguished from the driving mold casing unit covering the driving unit by a difference in mold thickness.

24. The sound transmission device of claim 22, wherein a support line is provided along an outer circumferential edge of the casing molding unit to maintain the outer appearance.

25. The sound transmission device of claim 22, wherein a microphone is further mounted within the casing molding unit, and
a sound transmission hole is provided in the casing molding unit at a position corresponding to the microphone.

26. The sound transmission device of claim 25, wherein a sound passing hole corresponding to the sound transmission hole is provided in a protective cap covering the microphone, and
a mesh is bonded to the sound passing hole to provide waterproofing.

27. The sound transmission device of claim 22, wherein the protective cap comprises a button receiving portion provided on the partition and receiving the button.

28. The sound transmission device of claim 27, wherein a positioning hole is provided in the button receiving portion to determine the positions of the switch and the button, and
a protrusion extending from the button is inserted into the positioning hole.

29. The sound transmission device of claim 22, wherein a portion of the clamp extends outside the board, and
a clamp molding unit corresponding to the portion of the clamp extending outside the board is molded integrally with the casing molding unit.
